(19) United States
(12) Patent Application Publication
(10) Pub. No.: US 2023/0364641 A1
(43) Pub. Date: Nov. 16, 2023

(54) METHOD FOR ALTERING THE SURFACE CONDITION OF A PART BY ION BOMBARDMENT

(71) Applicant: Rubattel & Weyermann S.A., La Chaux-de-Fonds (CH)

(72) Inventors: Giovanni POLY, Villers-Le-Lac (FR); Corina Barbos, La Chaux-de-Fonds (CH); Frédéric Jeanrenaud, La Chaux-de-Fonds (CH)

(73) Assignee: Rubattel & Weyermann S.A., La Chaux-de-Fonds (CH)

(21) Appl. No.: 18/161,212

(22) Filed: Jan. 30, 2023

(30) Foreign Application Priority Data
May 10, 2022 (EP) 22172494.1

(51) Int. Cl. B05D 7/26; B05D 5/02; B05D 3/14; B05D 3/06

(52) U.S. Cl. CPC B05D 7/26; B05D 3/067; B05D 3/148; B05D 5/02; B05D 2501/00

(57) ABSTRACT

A method for plasma treating a target surface of a part, including: obtaining the target surface on the part; placing the part in a chamber of a plasma generator; evacuating the chamber to a pressure of between 10⁻⁶ and 10 mbar; injecting a suitable gas into the chamber until a pressure in the chamber of between 10⁻⁴ and 10² mbar is reached; generating an electric current discharge within the chamber, via an electric generator, in order to generate a plasma; exposing the target surface of the part to the plasma for a predefined period of time depending on the power of the electric current discharge, on the gas injected into the chamber and on the material of the target surface, so as to deteriorate the surface condition of the target surface in order to increase the roughness thereof to make the target surface mat or more mat.

### CROSS REFERENCE TO RELATED APPLICATIONS

This application claims priority to European Patent Application No. 22172494.1, filed on May 10, 2022, the entire contents of which are incorporated herein by reference.

### TECHNICAL FIELD OF THE INVENTION

The invention relates to the field of surface treatments, and in particular to a method for altering the surface condition of a surface of a part by ion bombardment.

### TECHNOLOGICAL BACKGROUND

In some applications, in particular for aesthetic reasons in the case of external parts, efforts are made to obtain a visible surface with a mat, i.e. non-glossy, appearance.

In other words, efforts are made to mat the surface of certain external parts, i.e. increase the mattness thereof.

Typically, a mat appearance is obtained for a surface of a part by increasing the roughness thereof. More specifically, the gloss of a surface depends on to what extent it reflects light radiation. In particular, a surface with a glossy appearance reflects light specularly, and a surface with a mat appearance reflects light diffusely.

In order to mat a surface of a part, known solutions consist of projecting, onto the surface, particles of abrasive material, the particle size whereof varies according to the desired result, with a defined pressure and over a given period of time. The particles of abrasive material can be beads made of glass, ceramic or aluminium oxide, etc.

However, the drawback of these solutions is that the abrasive materials are subject to wear and require special waste treatment after use. This is because the abrasive material particles are contaminated with particles of material from the part whose surface is to be matted as a result of their use. Moreover, there is a significant risk that disparities exist in the particle sizes of the particles of abrasive material. Finally, depending on the thickness of the part, projecting particles can cause irreversible damage or deformation.

In other cases, the nature of the material of all or some of the part can be altered so as to mat the surface thereof. In particular, in the case where the surface to be matted is the surface of a varnish coat deposited on the part, appropriate resins or additives can be added to the varnish composition.

However, this solution is limited as it only applies in the presence of a surface of a varnish coat. Furthermore, following the alteration of its composition, the varnish coat may no longer meet certain requirements, such as being able to withstand mechanical or chemical stresses, being able to withstand certain temperatures to an extent, or being able to withstand exposure to ultraviolet radiation, etc. Another drawback of this solution is that it adds an additional step to the production of an external part that involves altering the composition of the varnish, which is particularly restrictive when such a part must be produced on an industrial scale.

### SUMMARY OF THE INVENTION

The invention overcomes the aforementioned drawbacks by providing a solution for matting a target surface, i.e. for increasing the mattness thereof, without creating an oxide on said surface, or any coating.

In other words, the present invention allows only the surface condition of the target surface to be altered in order to mat it.

For this purpose, the present invention relates to a method for plasma treating a target surface of a part, including the following steps of:
obtaining the target surface on the part, comprising an operation of depositing a coat of varnish on a dedicated area of the target surface and an operation of pre-crosslinking at least a portion of the varnish coat by exposing at least a portion of the target surface to ultraviolet radiation;
   placing the part in a chamber of a plasma generator,
   evacuating the chamber to a pressure of between 10⁻⁶ and 10 mbar,
   injecting a suitable gas into the chamber until a pressure in the chamber of between 10⁻⁴ and 10² mbar is reached,
   generating an electric current discharge within the chamber, via an electric generator, in order to generate a plasma,
   exposing the target surface of the part to the plasma for a predefined period of time, depending in particular on the power of the electric current discharge, the gas injected into the chamber and the material of the target surface, so as to alter the surface condition of the target surface in order to increase the roughness thereof to make said target surface mat or more mat, i.e. to mat it, said step of exposing the target surface of the part to the plasma being carried out so as to finish the crosslinking of the portion of the pre-crosslinked varnish coat.

In particular implementations, the invention can further include one or more of the following features, taken alone or according to any combination technically possible.

In particular implementations, during the pre-crosslinking operation, the target surface is exposed to the ultraviolet radiation for 5 to 10 seconds.

In particular implementations, the chamber is evacuated to a pressure of between 0.1 and 1 mbar.

In particular implementations, argon is injected during the gas injection step. This gas is injected into the chamber at a mass flow rate of between 15 and 25 sccm, until a pressure of between 0.6 and 0.8 mbar is reached in the chamber.

Advantageously, the choice of argon as the gas from which the plasma is generated means that the target surface is only affected mechanically. In other words, the plasma does not chemically degrade the surface condition of the target surface.

In particular implementations, the electric generator develops a power of between 2,000 and 2,600 W during the step of generating an electric current discharge and the step of exposing the target surface is carried out for 1 to 2 minutes.

In particular implementations, the varnish coat has a gloss unit measured at 60° of less than 5 GU.

In particular implementations, at the end of the step of obtaining the target surface on the part, a step of depositing a masking layer is carried out over a portion of the target surface referred to as the “masked area”, the remainder of said target surface being referred to as the “exposed area”, said masking layer being intended to protect the masked area from the plasma.

In particular implementations, during the pre-crosslinking operation for the varnish coat, only a portion of said coat is pre-crosslinked, the other portion being fully crosslinked.

### BRIEF DESCRIPTION OF THE FIGURES

Other features and advantages of the invention will become apparent upon reading the following detailed description given by way of a non-limiting example, with reference to the accompanying drawings in which:

FIGS. 1 to 4 diagrammatically show different successive steps of a method for plasma treating a target surface of a part according to a preferred example implementation of the invention;

FIG. 5 diagrammatically shows a cross-sectional view of a step of exposing the target surface of the part to the plasma according to an alternative to the preferred example implementation of the method according to the invention;

FIG. 6 diagrammatically shows a cross-sectional view of a step of exposing the target surface of the part to the plasma according to another example implementation of the method according to the invention.

It should be noted that the figures are not drawn to scale for clarity purposes.

### DETAILED DESCRIPTION OF THE INVENTION

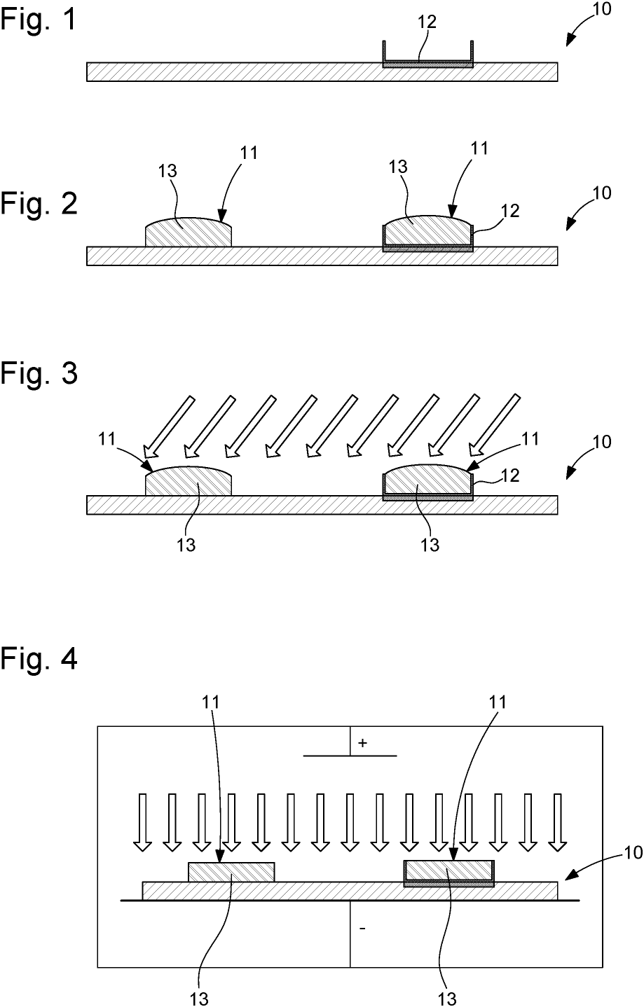

FIGS. 1 to 4 diagrammatically show different successive steps of a method for plasma treating a target surface 11 of a part 10 according to a preferred example implementation of the present invention.

The method according to the invention aims to mat the target surface 11.

The method comprises a preliminary step of obtaining the target surface 11 on the part 10.

This preliminary step can include operations involving depositing a coating, for example a galvanic coating, placing an applique, printing a decoration, or washing, etc.

FIG. 1 diagrammatically shows a part 10 comprising an applique 12 intended to receive a coat of varnish 13.

In the preferred example implementation of the invention, during this first step, an operation is carried out to deposit a coat of varnish 13 on a dedicated area of an external surface of the part 10, as shown in FIG. 2. More specifically, the dedicated area can be formed on the applique 12 previously placed on the external surface of the part and/or directly formed on the external surface of the part 10, as shown in FIGS. 2 to 5.

Still in this preliminary step, this operation of depositing a coat of varnish 13 is followed by an operation of pre-crosslinking the coat of varnish 13 by exposure to ultraviolet radiation, as shown in FIG. 3. The target surface 11 is, in this example embodiment of the invention, the visible surface of the varnish coat 13.

The varnish coat 13 can be deposited manually by an operator or automatically by a suitable robot. Moreover, the varnish coat 13 can include a synthetic, acrylic, polyurethane or polyepoxide resin, or a luminescent material, etc.

During the operation of pre-crosslinking the varnish coat 13, the target surface 11 can be exposed to the ultraviolet radiation for a few seconds or a few tens of seconds, preferably between 5 and 10 seconds.

The ultraviolet radiation can be emitted by any means known to a person skilled in the art, such as a light-emitting diode or mercury-vapour lamp, etc., so as to have a wavelength between 100 and 400 nm.

Once the target surface 11 has been obtained, the part 10 is placed in a chamber of a plasma generator 20, as shown in FIG. 4. In particular, the part 10 is disposed on an electrode of an electric generator of the plasma generator 20, either directly thereon or via a substrate. Preferably, the part 10 is disposed on the negative electrode of the plasma generator 20, facing the positive electrode.

The method according to the invention then includes a step of evacuating the chamber by means of a vacuum pump known as such to a person skilled in the art. The term “evacuation” here is understood, for linguistic simplification, to mean that the chamber is put under low pressure, typically a pressure of between 10⁻⁶ and 10 mbar, and preferably between 0.1 and 1 mbar.

A gas injection step is then implemented until a working pressure of between 10⁻⁴ and 10² mbar is reached in the chamber, and preferably a working pressure of between 0.6 and 0.8 mbar.

For example, the gas is injected at a mass flow rate of between 15 and 25 sccm until the chamber reaches the working pressure.

A step of generating an electric current discharge within the chamber is carried out, via the electric generator, in order to generate a plasma within said chamber. The plasma flow is advantageously directed towards the part 10, so as to cause ion bombardment on the target surface 11, as diagrammatically shown in FIG. 4. In particular, the potential difference between the electrodes of the electric generator causes the gas atoms to be ionised and bombard the target surface 11 of the part 10.

The gas used, which is suitable for the implementation of the method according to the invention, can be chosen from Ar, He, O₂, CO, CO₂, H₂, Cl₂, CF₄, Ne, N₂ and NO₂. Ar is the preferred gas as it is easily ionisable, allowing a plasma to be generated with a reduced electrical input. Moreover, the effect of the plasma on the target surface 11 is more important when it is carried out with Ar, in that said plasma is particularly well suited for altering the surface condition of the target surface 11 and crosslinking an optional varnish coat 13 deposited on the part 10. Finally, Ar has the advantage of being inexpensive and easy to obtain.

The target surface 11 is exposed to the plasma for a predefined period of time depending in particular on the power of the electric current discharge, on the gas injected into the chamber and on the material of the target surface 11, so as to alter the surface condition of said target surface 11 to increase the roughness thereof and thus the mattness thereof. In the present invention, the exposure of the target surface 11 to the plasma, and in particular to the ion bombardment, has the effect of altering the surface condition of said target surface 11 by mechanical action or by physical-chemical action, depending on the gas injected into the chamber.

In the preferred example implementation of the present invention, the step of exposing the target surface 11 of the part 10 to plasma is carried out so as to complete the crosslinking of the varnish coat 13.

For example, in the step of generating an electric current discharge, the electric generator can develop a power of between 2,000 and 2,600 W and the target surface 11 can be exposed for 1 to 2 minutes.

Also by way of example, after the method has been implemented, the varnish coat 13 has a gloss unit measured at 60° of less than 5 GU. In other words, the aforementioned parameters have been specifically determined by the inventors such that the target surface 11 of the varnish coat 13 has such a gloss unit.

One of the advantages of the present invention is that it allows the varnish coat 13 to be crosslinked and the target surface 11 to be matted at the same time, when the part 10 is exposed to the plasma. Thus, in addition to generating significant gains in production time by avoiding the need for a subsequent crosslinking step, the present invention reduces the time of exposure to the ultraviolet radiation, and thus limits the risks associated with the use of ultraviolet radiation.

The present invention further allows, according to any example embodiment of the invention considered, the mattness of any surface to be increased, regardless of its surface condition, for example even if it has cavities of sub-micrometric or micrometric dimensions.

Advantageously, at the end of the step of obtaining the target surface 11 on the part 10, a step of depositing a masking layer can be carried out over a portion of the target surface 11 referred to as the “masked area”, the remainder of said target surface 11 being referred to as the “exposed area”. Said masking layer is intended to protect the masked area from the effects of the plasma, so as to obtain a part 10 whose target surface 11 has two different gloss levels.

This step of depositing a masking layer can thus be used to obtain a part 10 whose target surface 11 is both glossy and mat.

The masking layer can be produced by a polymer coating, a galvanic coating or a coating made by a physical vapour deposition method.

Following the step of exposing the target surface 11 to the plasma, the masking layer can be removed by a solution that is adapted to the nature of the deposited coating. For example, if the masking layer is made of a polymer material, it can be removed with a suitable solvent, if it is made of a metal material, it can be removed with an acidic solution, etc.

Where necessary, the portion of the varnish coat 13 protected by the masking layer can be crosslinked in a subsequent crosslinking step.

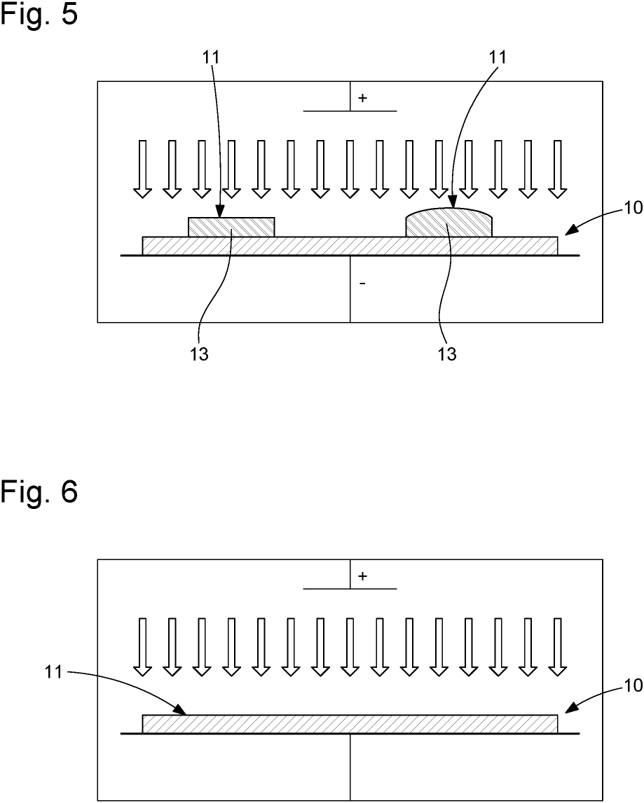

In the preferred example implementation of the invention, during the operation of pre-crosslinking the varnish coat 13, only a portion of said varnish coat 13 can be pre-crosslinked, the other portion thus being fully crosslinked. Since the fully crosslinked portion of the varnish coat 13 is not crosslinked by the plasma, the surface condition thereof remains unaltered or is altered in a way that is not perceptible to the naked eye, as diagrammatically shown in FIG. 5.

Such a feature allows a part 10 with a target surface 11 of different gloss levels to be obtained, as an alternative to the deposition of a masking layer.

In one example embodiment diagrammatically shown in FIG. 6, in contrast to the example embodiment shown in FIGS. 1 to 4, the target surface 11 is formed by the surface of the part 10 or by the surface of a coating of said part 10. In other words, in this example implementation of the present invention, the surface to be matted is that of the part 10 or of a coating of the part 10, and not that of a varnish 13 deposited on the part 10.

Such an example embodiment is particularly suitable when the target surface 11 is a surface of a part made of a metal alloy, such as a copper, iron, aluminium, or titanium alloy, etc., a ceramic material, such as a metal material coupled with oxides, nitrites or silicates, a composite material or a polymer material. This example embodiment of the invention is also particularly suitable when the target surface 11 is a surface of a gold, silver, nickel, copper, rhodium, ruthenium or silver, etc. coating of the part 10.

Depending on the material of the part 10 or of the coating of the part 10 having the target surface 11, the values of the parameters of the method according to the invention can vary. For example, the mass flow rate of the gas injection into the chamber can be up to 1,000 sccm, the power of the electric generator can be up to 4 kW, and the duration of plasma exposure can be between a few seconds and a few minutes, for example between 5 seconds and 10 minutes.

The present invention advantageously applies to the horological field, in particular when the part 10 is an external part 10 of a watch, for example a dial.

More generally, it should be noted that the implementations and embodiments considered above have been described by way of non-limiting examples, and that other variants are consequently possible.

1. A method for plasma treating a target surface of a part including the following steps of:
obtaining the target surface on the part, comprising an operation of depositing a coat of varnish on a dedicated area of the target surface and an operation of pre-crosslinking at least a portion of the coat of varnish by exposing at least a portion of the target surface to ultraviolet radiation;
placing the part in a chamber of a plasma generator;
evacuating the chamber to a pressure of between 10⁻⁶ and 10 mbar;
injecting a suitable gas into the chamber until a pressure in the chamber of between 10⁻⁴ and 10² mbar is reached;
generating an electric current discharge within the chamber, via an electric generator, in order to generate a plasma; and
exposing the target surface of the part to the plasma for a predefined period of time, depending at least on the power of the electric current discharge, the gas injected into the chamber and the material of the target surface, so as to deteriorate the surface condition of the target surface in order to increase the roughness thereof to mat said target surface, said step of exposing the target surface of the part to the plasma being carried out so as to finish the crosslinking of the portion of the pre-crosslinked varnish coat.

2. The treatment method according to claim 1, wherein, during the pre-crosslinking operation, the target surface is exposed to the ultraviolet radiation for 5 to 10 seconds.

3. The treatment method according to claim 1, wherein the chamber is evacuated to a pressure of between 0.1 and 1 mbar.

4. The treatment method according to claim 1, wherein, during the gas injection step, argon is injected into the chamber at a mass flow rate of between 15 and 25 sccm, until a pressure of between 0.6 and 0.8 mbar is reached in the chamber.

5. The treatment method according to claim 4, wherein the electric generator develops a power of between 2,000 and 2,600 W during the step of generating an electric current discharge and the step of exposing the target surface is carried out for 1 to 2 minutes.

6. The treatment method according to claim 1, wherein the varnish coat has a gloss unit measured at 60° of less than 5 GU.

7. The treatment method according to claim 1, wherein, at the end of the step of obtaining the target surface on the part, a step of depositing a masking layer is carried out over a portion of the target surface corresponding to a masked area, the remainder of said target surface corresponding to an exposed area, said masking layer being configured to protect the masked area from the plasma.

8. The treatment method according to claim 1, wherein, during the pre-crosslinking operation for the varnish coat, only a portion of said coat is pre-crosslinked, the other portion being fully crosslinked.
